(19) United States
(12) Patent Application Publication
(10) Pub. No.: US 2019/0246490 A1
(43) Pub. Date: Aug. 8, 2019

(54) CIRCUIT BOARD, MANUFACTURING METHOD FOR CIRCUIT BOARD AND CAMERA MODULE

(71) Applicants: TRIPLE WIN TECHNOLOGY(SHENZHEN) CO.LTD., Shenzhen (CN); HON HAI PRECISION INDUSTRY CO., LTD., New Taipei (TW)

(72) Inventors: JING-WEI LI, Shenzhen (CN); SHIN-WEN CHEN, New Taipei (TW); KUN LI, Shenzhen (CN); SHENG-JIE DING, Shenzhen (CN)

(21) Appl. No.: 15/907,435

(22) Filed: Feb. 28, 2018

(30) Foreign Application Priority Data
Feb. 2, 2018 (CN) 201810105970.6

(51) Int. Cl. H05K 1/02; H05K 1/18; H04N 5/225

(52) U.S. Cl. CPC H05K 1/0206; H05K 1/0274; H05K 1/181; H05K 2201/10151; H04N 5/2254; H04N 5/2258; H05K 2201/10121; H04N 5/2253

(57) ABSTRACT

The present invention relates to a camera module. The camera module includes a circuit board; an image sensor electrically connected to the circuit board; at least one lens holder disposed on the circuit board; at least one lens module received in the at least one lens holder; wherein the circuit board comprises a heat dissipation area in the central thereof and a wiring area besides the heat dissipation area, the wiring area being electrically insulated from the heat dissipation area, the wiring area comprises a plurality of conducting traces, the heat dissipation area defines a plurality of dissipating holes, each dissipating hole is provided with a thermally conductive pillar; and the image sensor is mounted on the heat dissipation area, heat generated by the image sensor is able to dissipate via the thermally conductive pillar.

### FIELD

The subject matter herein generally relates to a circuit board, manufacturing method for circuit board and a camera module.

### BACKGROUND

Since the camera size is miniaturized and has many features, such as the number of pixels being increased, the complexity of circuits for control is increased. When complexity is increased, space between the elements in the circuits is reduced, thus a considerable amount of heat is generated in a camera module. Therefore, the effective dissipation of heat from camera modules is problematic.

### BRIEF DESCRIPTION OF THE DRAWINGS

Implementations of the present technology will now be described, by way of example only, with reference to the attached figures.

FIG. 1 is an isometric view of a camera module in accordance with one exemplary embodiment.

FIG. 2 is one exploded isometric view of the camera module in FIG. 1.

FIG. 3 is another exploded isometric view of the camera module in FIG. 1.

FIG. 4 is a cross-sectional view of the camera module in FIG. 1 along line IV-IV direction.

FIG. 5 is a flowchart of a manufacturing method for the circuit board in FIG. 1.

FIG. 6 is a cross sectional view of providing a single side copper cladding substrate.

FIG. 7 is a cross sectional view of forming conducting traces on an insulating layer in FIG. 6.

FIG. 8 is a cross sectional view of forming a cover layer on the conductive layer.

FIG. 9 is a cross sectional view of forming a plurality of blind holes in the insulating layer.

FIG. 10 is a cross sectional view of filling thermally conductive material in the plurality of blind holes.

FIG. 11 is a cross sectional view of forming a metal reflecting layer on the bottom of the insulating layer and obtaining the circuit board in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better. The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like. The references “a plurality of” and “a number of” mean “at least two.”

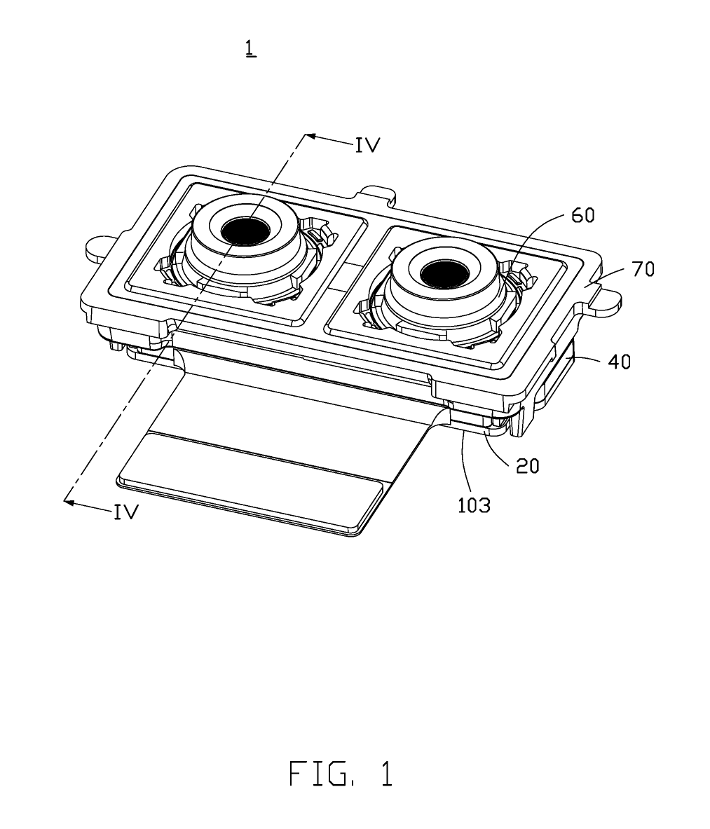

FIG. 1˜4 illustrate a camera module 1 having for example an automatic focusing double-camera. The device 1 can also be used as a fixed focus module and as a automatic focusing single lens module.

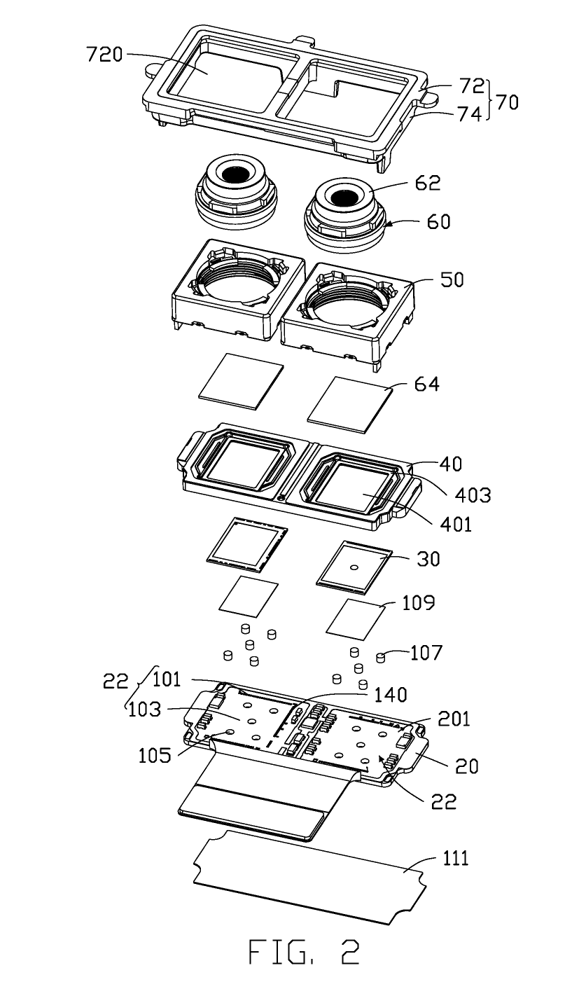

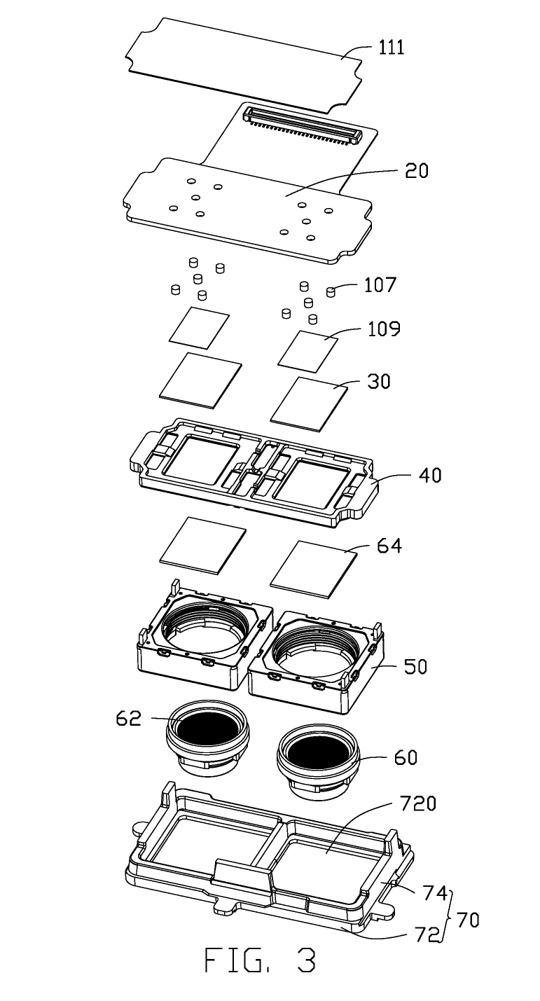

The camera module 1 includes a circuit board 20, an image sensor 30 electrically connected to the circuit board 20, a pedestal 40, two lens holders 50, two lens modules 60 and an upper cover bracket 70, as shown in FIG. 2.

The circuit board 20 is substantially rectangular and includes two portions 22. Each portion 22 is configured to mounted an image sensors 30. Each portion 22 defines a central heat dissipation area 103 and a wiring area 101 surrounding the heat dissipation area 103. The wiring area 101 includes a plurality of conducting traces 140. The conductive traces 140 are configured to electrically connect to the image sensor 30. The location relationship between the heat dissipation area 103 and the wiring area 101 can be designed according to real needs. The wiring area 101 is electrically insulated from the heat dissipation area 103, to have no effect on the conductive traces 140 of the wiring area 101.

The heat dissipation area 103 defines a plurality of blind holes 105 passing through the insulating layer 12, and the blind holes 105 expose the copper layer 14 at the heat dissipation area 103. The blind holes 105 are spaced apart each other. Each dissipating hole 105 is infilled with thermally conductive material and the thermally conductive material forms a thermally conductive pillar 107. The thermally conductive pillar 107 is a metal, such us copper, aluminum and so on. In other embodiments, a plurality of thermally conductive pillars 107 are directly provided, and each thermally conductive pillar 107 is mounted in each blind holes 105.

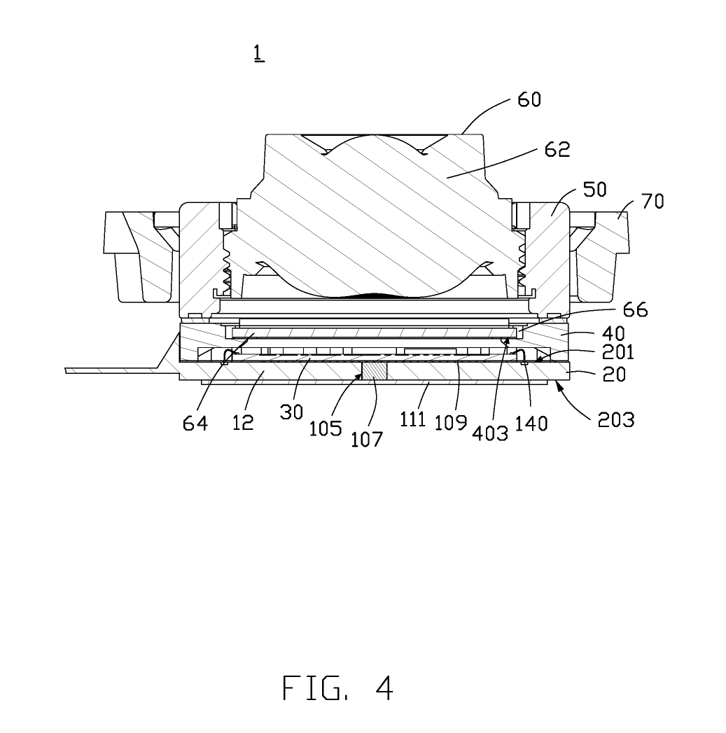

The image sensor 30 is mounted on the heat dissipation area 103, as shown in FIG. 4. The circuit board 20 includes a top surface 201 and a bottom surface 203 opposite to the top surface 201. The heat dissipation area 103 and the wiring area 101 are defined on the top surface 201. A heat dissipation layer 109 is formed on the heat dissipation area 103, an area of the heat dissipation area 103 is substantially equal to a size of the image sensor 30 or is slightly smaller than the image sensor 30. The image sensor 30 is mounted on the heat dissipation layer 109.

A metal reflecting layer 111 is formed on the bottom surface 203. The heat dissipation layer 109 and the metal reflecting area 111 are mounted at opposite ends of the thermally conductive pillar 107. The metal reflecting layer 111 is made from copper. When the camera module 1 is assembled on a mobile phone or a computer or other mobile terminal, the electromagnetic wave generated by an antenna of the mobile terminal is able to reflect by the metal reflection layer 111 of the bottom surface 203 of the circuit board 20. Electrical noise incident into the lens module 60 is thus avoided.

The circuit board 20 is provided with a plurality of blind holes 105, and the blind holes 105 are each filled with thermally conductive material, the thermally conductive material forms a thermally conductive pillar 107, each thermally conductive pillar 107 contacts the heat dissipation layer 109 and the metal reflective layer 111, and the image sensor 30 is arranged on the heat radiating layer 109. Thereby, heat generated by the image sensor 30 is conducted via the heat radiating layer 109, the thermally conductive pillar 107 and the metal reflective layer 111 and radiated out from the camera module 1, to avoid heat accumulation in the camera module 1.

The pedestal 40 is substantially rectangular and includes two light through holes 401 spaced apart from each other. Each light through holes 401 is surrounded by a stepping portion 403. The stepping portion 403 is configured to receive an optical filter 64 of the lens module 60.

The lens holder 50 is substantially square and mounted on the pedestal 40. In the illustrated embodiment, the lens holder 50 is a voice coil motor to realize automatic focusing of the lens module 60.

The lens module 60 is arranged in the lens holder 50. The lens module 60 may include only one optical lens or include a plurality of optical lenses 62. The lens module 60 also includes an optical filter 64 at its object end. The optical filter 64 is an infrared cut-off filter. The optical filter 64 is fixed on the stepping portion 403 by a double-sided adhesive (not shown). And a gap 66 is formed between the optical filter 64 and sidewall of the stepping portion 403, to expose a portion of the double-sided glue, if the lens module 60 and the lens holder 50 produce debris, the debris will be received in the gap and adsorbed by the double-sided glue exposed by the filter plate 64.

The upper cover bracket 70 is arranged on the two lens holders 50. The upper cover bracket 70 includes a top plate 72 and a side plate 74 extending vertically along edge of the top plate 72. The top plate 72 is provided with two light incidence holes 720. The top plate 72 is covered on the lens module 60, and the side plate 74 is enclosed periphery of the lens module group 60. The upper cover bracket 70 is configured to protect the lens module 60.

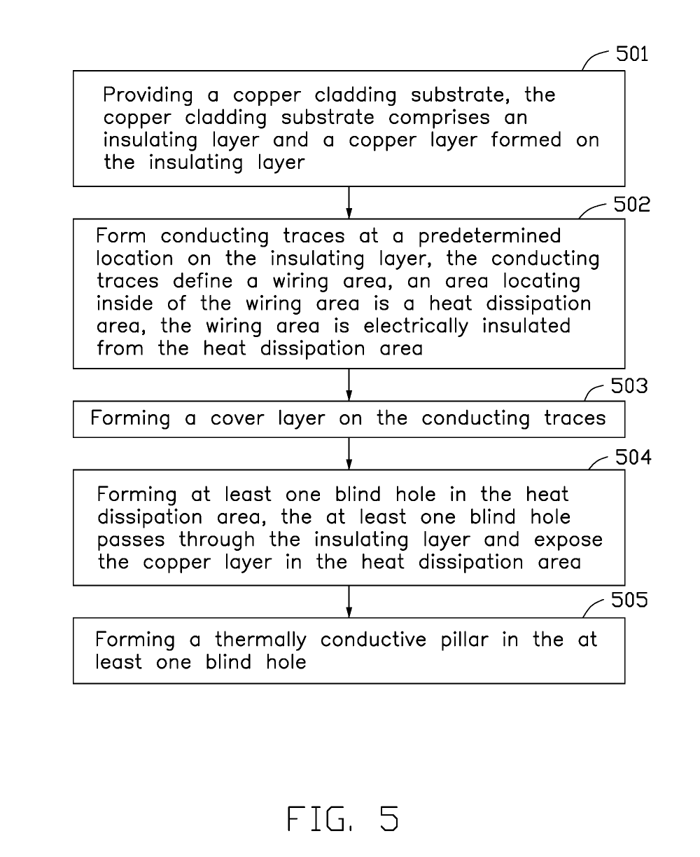

FIG. 5 illustrates a method for manufacturing the circuit board according to one embodiment. The method is provided by way of example as there are a variety of ways to carry out the method. The method 300 can be used to manufacture hardware components, industrial machinery components and so on.

At block 501, as shown in FIG. 6, a copper cladding substrate 10 is provided. The copper cladding substrate 10 includes an insulating layer 12 and a copper layer 14 formed on the insulating layer 12.

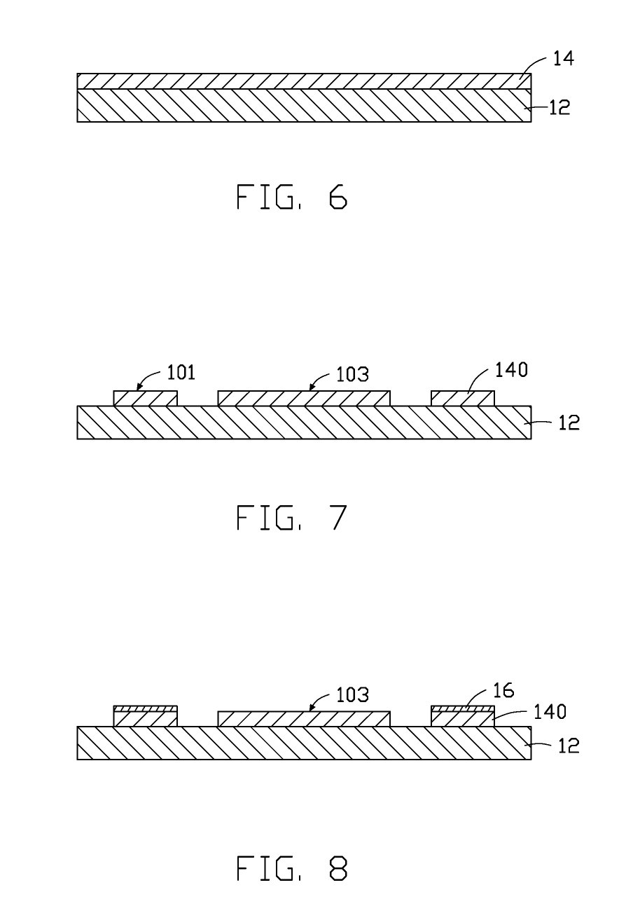

At block 502, as shown in FIG. 7 the copper layer 14 is etched to form conducting traces 140 at a predetermined location. In the illustrated embodiment, the conducting traces 140 is formed on edge of the insulating layer 12, and the conducting traces 140 define a wiring area 101, and an area locating inside of the wiring area 101 is a heat dissipation area 103. The wiring area 101 is electrically insulated from the heat dissipation area 103. The copper layer 14 is in the heat dissipation area 103, which is defined as part of the heat dissipation layer 109.

At block 503, as shown in FIG. 8, a cover layer 16 is formed on the conducting traces 140. The cover layer 16 is configured to protect the conducting traces 140. In the illustrated embodiment, the cover layer 16 is solder mask.

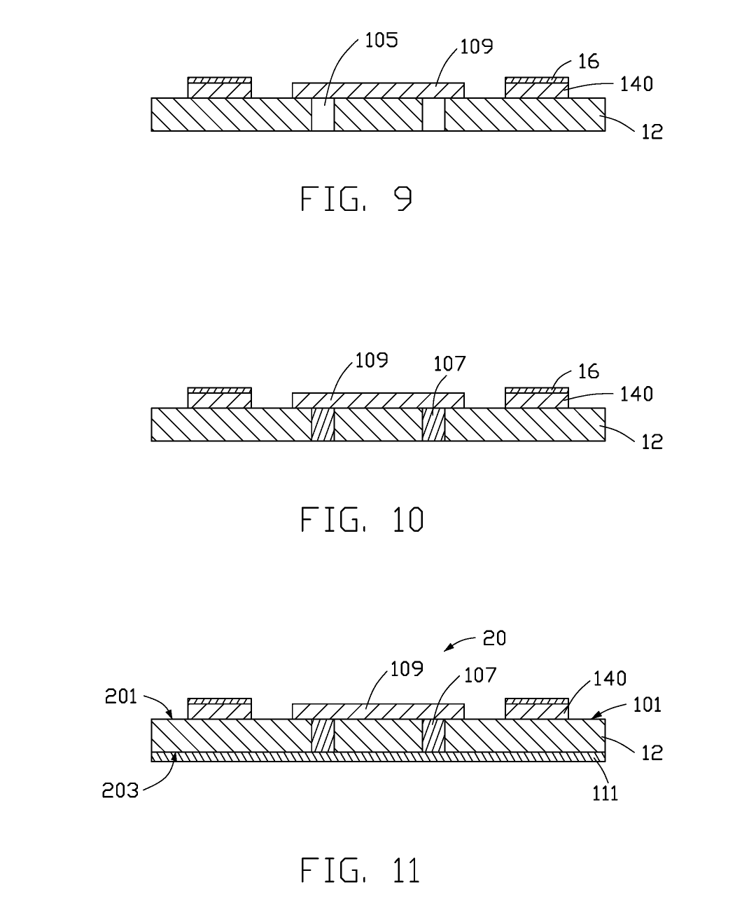

At block 504, as shown in FIG. 9, a plurality of blind holes 105 is formed in the heat dissipation area 103. The blind holes 105 pass through the insulating layer 12 and expose the heat dissipation layer 109. The blind holes 105 can be formed by laser ablation.

At block 505, as shown in FIG. 10, a thermally conductive material is filled into the blind holes 105, and the blind holes 105 forms a thermally conductive pillar 107. The thermally conductive pillar 107 is a metal with high thermal conductivity, such us copper, aluminum and so on. In other embodiment, the thermally conductive pillar 107 is preformed and then directly assembled into the dissipating hole 105.

At block 506, as shown in FIG. 11, a metal reflecting layer 111 is formed on bottom of the insulating layer 12. Two opposite ends of the thermally conductive pillar 107 contacts the heat dissipation layer 109 and the metal reflecting layer 111. The metal reflecting layer 111 is made from copper. The metal reflecting layer 111 can be formed by electroplating or depositing or directly pressing a single layer of copper foil on the bottom of the insulting layer 12. It may also be understood that the metal reflecting layer 111 may also be a copper foil provided by a double-sided copper cladding substrate.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A circuit board comprising:
a heat dissipation area in the central thereof and a wiring area besides the heat dissipation area, the wiring area being electrically insulated from the heat dissipation area, the wiring area comprises a plurality of conducting traces, the heat dissipation area defines a plurality of dissipating holes passing through the circuit board, each dissipating hole is provided with a thermally conductive pillar.

2. The circuit board of claim 1, wherein the circuit board comprises a top surface and a bottom surface opposite to the top surface, the heat dissipation area and the wiring area are arranged on the top surface, and the heat dissipation area is formed with a heat dissipation layer.

3. The circuit board of claim 2, wherein the bottom surface is formed with a metal reflecting layer, the thermally conductive pillar contacts the heat dissipation layer and the metal reflecting layer.

4. The circuit board of claim 3, wherein the metal reflecting layer is made from copper.

5. A method for forming a circuit board, comprising:
providing a copper cladding substrate, the copper cladding substrate comprises an insulating layer and a copper layer formed on the insulating layer;
forming conducting traces at a predetermined location on the insulating layer, the conducting traces define a wiring area, an area locating inside of the wiring area is a heat dissipation area, the wiring area is electrically insulated from the heat dissipation area;
forming a cover layer on the conducting traces;
forming at least one blind hole in the heat dissipation area, the at least one blind hole passes through the insulating layer and exposes the copper layer in the heat dissipation area; and
forming a thermally conductive pillar in the at least one blind hole.

6. The method of claim 5, wherein the circuit board comprises a top surface and a bottom surface opposite to the top surface, the heat dissipation area and the wiring area are arranged on the top surface, the heat dissipation area is formed with a heat dissipation layer.

7. The method of claim 6, wherein the bottom surface is formed with a metal reflecting layer, and the thermally conductive pillar contacts the heat dissipation layer and the metal reflecting layer.

8. The method of claim 7, wherein the metal reflecting layer is copper.

9. The method of claim 7, wherein the metal reflecting layer is formed by electroplating, or depositing, or directly pressing a single layer of copper foil on the bottom of the insulting layer.

10. A camera module comprising:
a circuit board;
an image sensor electrically connected to the circuit board;
at least one lens holder disposed on the circuit board;
at least one lens module received in the at least one lens holder; wherein the circuit board comprises a heat dissipation area in the central thereof and a wiring area besides the heat dissipation area, the wiring area being electrically insulated from the heat dissipation area, the wiring area comprises a plurality of conducting traces, the heat dissipation area defines a plurality of dissipating holes passing the circuit board, each dissipating hole is provided with a thermally conductive pillar; and
wherein the image sensor is mounted on the heat dissipation area, heat generated by the image sensor is able to dissipate via the thermally conductive pillar.

11. The camera module of claim 10, wherein the circuit board comprises a top surface and a bottom surface opposite to the top surface, the heat dissipation area and the wiring area are arranged on the top surface, and the heat dissipation area is formed with a heat dissipation layer.

12. The camera module of claim 11, wherein the bottom surface is formed with a metal reflecting layer, the thermally conductive pillar contacts the heat dissipation layer and the metal reflecting layer.

13. The camera module of claim 12, wherein the metal reflecting layer is made from copper.

14. The camera module of claim 10, wherein the camera module is a double-camera module.

15. The camera module of claim 14, wherein the camera module further includes a pedestal, the pedestal is disposed on the circuit board, and the lens holder is disposed on the pedestal, the pedestal is substantially rectangle and comprises two light through holes, each light through hole is surrounded by a stepping portion.

16. The camera module of claim 15, wherein the lens module comprises an optical filter at its object end, the optical filter is fixed on the stepping portion, and a gap is formed between the optical filter and sidewall of the stepping portion.
